(19) United States
(12) Patent Application Publication
(10) Pub. No.: US 2026/0096393 A1
(43) Pub. Date: Apr. 2, 2026

(54) DEVICE AND METHOD FOR PROCESSING SEMICONDUCTOR STRUCTURE

(71) Applicant: Taiwan Semiconductor Manufacturing Company, Ltd., Hsinchu (TW)

(72) Inventors: Sheng-Wei Chou, Hsinchu (TW); Tzu Ken Lin, Taichung City (TW); Ching-Horng Chen, Hsinchu County (TW); Chen-Shien CHEN, Hsinchu County (TW); Po-Chen Chen, Hsinchu (TW)

(73) Assignee: Taiwan Semiconductor Manufacturing Company, Ltd., Hsinchu (TW)

(21) Appl. No.: 18/902,978

(22) Filed: Oct. 1, 2024

(51) Int. Cl. H01L 21/683; H01L 21/263

(52) U.S. Cl. CPC H10P 72/722; H10P 34/40

(57) ABSTRACT

A device includes a chuck. The chuck has an upper portion and a lower portion larger than the upper portion and includes first apertures, second apertures, third apertures and a gas supply channel. The first apertures are disposed at a top surface of the upper portion of the chuck. The second apertures are disposed at a sidewall of the upper portion of the chuck. The third apertures are disposed at a top surface of the lower portion of the chuck. The gas supply channel extends through the chuck and connecting the first apertures, the second apertures and the third apertures.

### BACKGROUND

Electrostatic chucks (ESCs) are widely used in various semiconductor processes to hold a wafer during different operations, such as plasma-based etching, ion implantation, chemical vapor deposition (CVD), etc. Therefore, the defects of the ESCs and the wafer are very important indicators in the semiconductor manufacturing industry to affect yield rate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor processing device.

FIGS. 2A to 2B illustrate a side view and a cross-sectional view of a chuck structure.

FIG. 3 illustrates a top view of a chuck of a chuck structure.

FIG. 4 illustrates a top view of a carrier plate of a chuck structure.

FIG. 5 illustrates a partial enlarged view of a semiconductor processing device of FIG. 1.

FIG. 6 illustrates a cross-sectional view of a chuck structure.

FIG. 7 illustrates a top view of a chuck of a chuck structure.

FIG. 8 illustrates a top view of a carrier plate of a chuck structure.

FIG. 9 illustrates a flowchart of a method with use of a semiconductor processing device including a chuck.

FIG. 10 illustrates a semiconductor device formed by using the method of FIG. 9.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

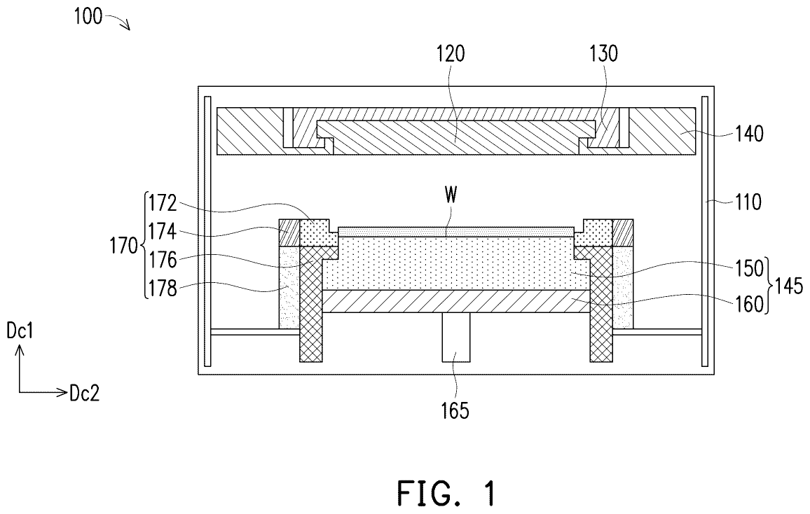

FIG. 1 illustrates a cross-sectional view of a semiconductor processing device.

Referring to FIG. 1, a semiconductor processing device 100 may perform various semiconductor processes. The semiconductor processing device 100 may be applied to any type of processing operation using plasma. In some embodiments, the semiconductor processing device 100 is applied to the wafer dicing process with use of plasma. However, the disclosure is not limited thereto. The semiconductor processing device 100 may be also applied to any suitable plasma-based process such as a plasma assisted chemical vapor deposition (PECVD) process, a plasma etching process, a deposition process or a diffusion process (e.g., ion implantation process).

The semiconductor processing device 100 may include a chamber wall 110, a shower head 120, a diffusion plate 130, a top shield ring 140, a chuck structure 145 including a chuck 150 and a carrier plate 160, a supporting element 165 and a ring structure 170. In some embodiments, the semiconductor processing device 100 further includes a communication interface (not shown) that displays the required operating parameters of the semiconductor process, such as a monitor.

The chamber wall 110 may form a containing space of a processing chamber. For example, the chamber wall 110 includes a vertical portion extending vertically and a horizontal portion extending horizontally, and the vertical portion and the horizontal portion are connected to form the containing space of the processing chamber. The chamber wall 110 may surround the components of the semiconductor processing device 100. The horizontal portion of chamber wall 110 may further support the ring structure 170. The chamber wall 110 is made of any suitable material such as Y₂O₃ (yttrium oxide).

The shower head 120, the diffusion plate 130 and the top shield ring 140 are disposed at the top of the processing chamber. For example, the shower head 120, the diffusion plate 130 and the top shield ring 140 are disposed over the chuck 150. The shower head 120 may include a plurality of gas channels (not shown) exposed to the processing chamber. For example, the gas channels respectively penetrate through the shower head 120, so that a predetermined amount of process gas from a gas source (not shown) may pass through the shower head 120 and then enter into the processing chamber within the chamber wall 110. In some embodiments, the process gas is provided for generating the plasma. The process gas may include nitrogen (N₂), hydrogen (H₂), argon (Ar), helium (He), fluorine (F₂), chlorine (Cl₂), oxygen (O₂), hydrogen bromide (HBr), hydrofluoric acid (HF), nitrogen trifluoride (NF₃), sulfur hexafluoride (SF₆), organofluorine compounds with the general molecular formula CₓF_{y} such as C₄F₈ and C₄F₆, the like or a combination thereof. In some embodiments, the process gas includes C₄F₈ and C₄F₆.

The top shield ring 130 may support the shower head 120. For example, the diffusion plate 130 covers and surrounds the shower head 120. The diffusion plate 130 may be made of any suitable material such as silicon or quartz. The diffusion plate 130 may include an upper electrode (not shown). The upper electrode is disposed at the top of the processing chamber and opposite to a lower electrode (not shown) of the supporting element 165 which is disposed at the bottom of the processing chamber. The upper electrode and the lower electrode are, for example, coupled to an upper RF (radio frequency) generator (not shown) and a lower RF generator (not shown) respectively. By using the upper and lower electrodes, the plasma may be generated from the process gas in the processing chamber with a power. The power is from about 10 watts (W) to about 4,000 W, for example. The upper electrode and the lower electrode may be made of any suitable material such as copper and be covered/encapsulated by any suitable material such as stainless steel.

The top shield ring 140 may support the diffusion plate 130 and the shower head 120. For example, the top shield ring 140 surrounds both the shower head 120 and the diffusion plate 130. The top shield ring 140 may facilitate the spreading of the plasma in the process chamber. The top shield ring 140 is made of any suitable material such as Y₂O₃.

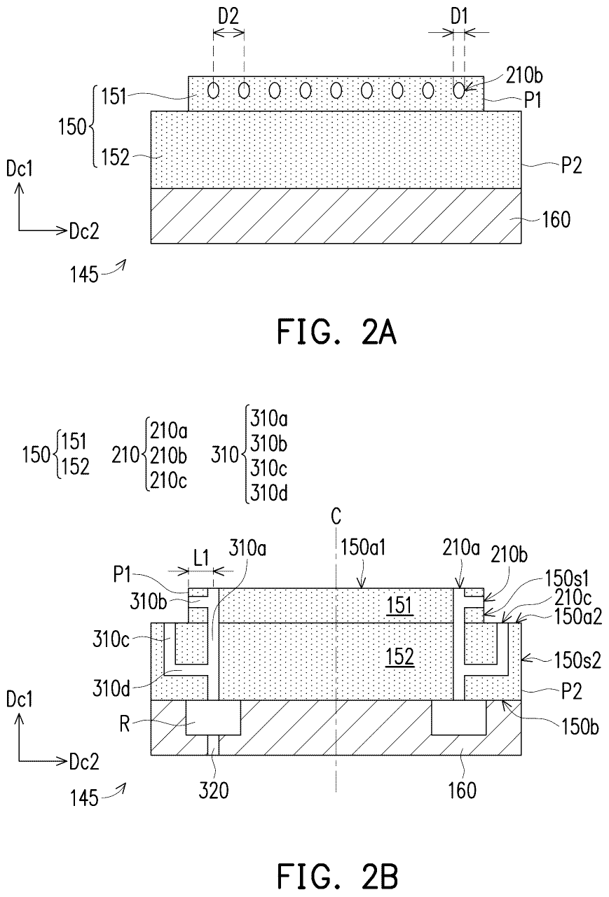

The chuck 150 may hold a semiconductor structure W during the semiconductor process. The semiconductor structure W may be a wafer. The chuck 150 is disposed at the bottom of the processing chamber. For example, the chuck 150 is disposed on the carrier plate 160 which is supported by the supporting element 165. The chuck 150 includes a plurality of apertures 210 and a gas supply channel 310 (shown in FIGS. 2A to 3 and 6 to 7) to deliver gas (e.g. gas for the heat dissipation and/or forming a gas wall). In some embodiments, the chuck 150 provides coulomb force to attract and hold the semiconductor structure W during the semiconductor process. The chuck 150 is also referred to as an electrostatic chuck (ESC). The semiconductor structure W is disposed on the chuck 150. A material of the chuck 150 may be SiO₂, Y₂O₃, Al₂O₃ or any suitable material that has better physical resistance against the plasma (e.g. epoxy for the plasma).

The carrier plate 160 may support the chuck 150. For example, the carrier plate 160 is disposed at the bottom of the processing chamber and between the chuck 150 and the supporting element 165. The carrier plate 160 may have recesses R (shown in FIG. 2B) below the chuck 150, to deliver the gas (e.g. the gas for the heat dissipation and/or forming the gas wall) into the gas supply channel 310 of the chuck 150. The carrier plate 160 is made of any suitable material such as such as aluminum.

The supporting element 165 may support the chuck 150 and the carrier plate 160. For example, the supporting element 165 is disposed at the bottom of the processing chamber and below the carrier plate 160. In some embodiments, the carrier plate 160 and the supporting element 165 are each a portion of an integrated molding structure.

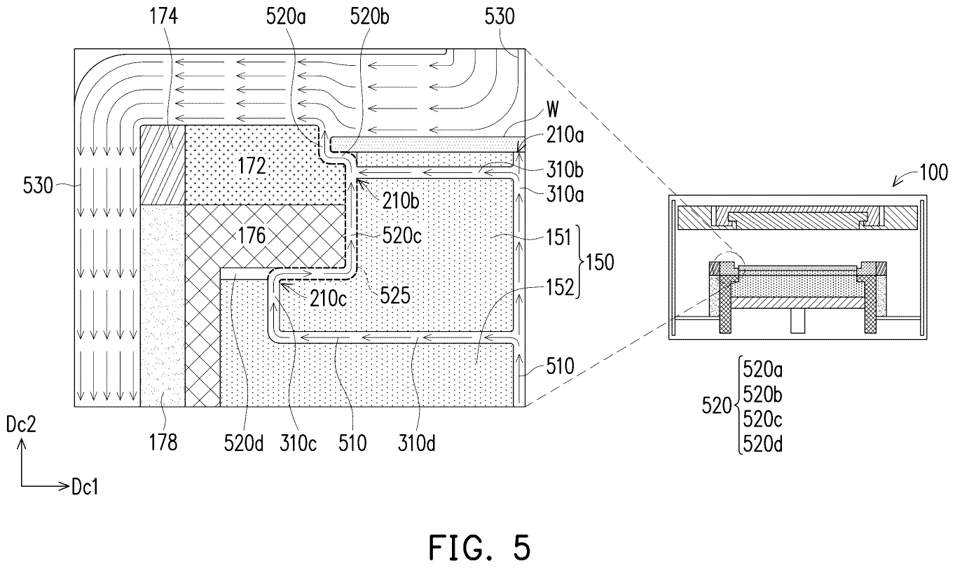

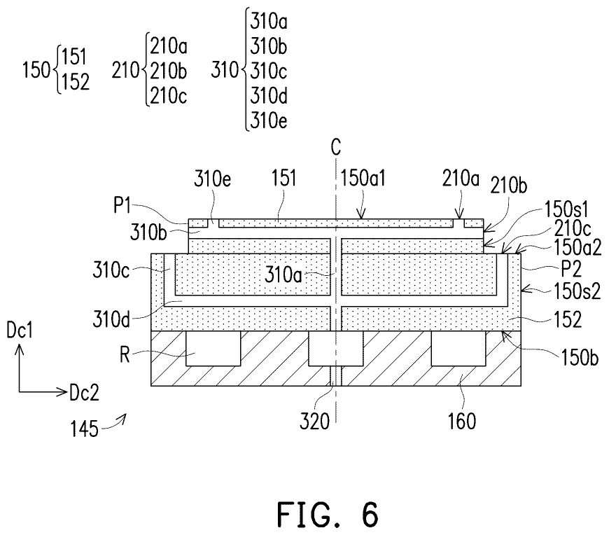

The ring structure 170 may protect the chuck 150. For example, the ring structure 170 is disposed on the horizontal portion of the chamber wall 110 and surrounds the semiconductor structure W, the chuck 150 and the carrier plate 160. The ring structure 170 may also improve etch uniformity near the edge or perimeter of the semiconductor structure W by allowing the plasma to spread beyond the semiconductor structure perimeter and concentrating the electric field within the ring structure 170. The ring structure 170 is a consumable part that is replaced regularly. The ring structure 170 may be an annular shape in a top view. In some embodiments, as shown in FIG. 2A and FIG. 5, the ring structure 170 surrounds a sidewall 150s1 of an upper portion 151 of the chuck 150 and surrounds a top surface 150a2 and a sidewall 150s2 of a lower portion 152 of the chuck 150.

In some embodiments, the ring structure 170 includes a focus ring 172, a cover ring 174, an inner ring 176, and an outer ring 178. The focus ring 172, the cover ring 174, the inner ring 176, and the outer ring 178 are annular shape in a top view, respectively. The focus ring 172 may surround a sidewall of the semiconductor structure W and the sidewall 150s1 of the upper portion 151 of the chuck 150 as shown in FIG. 5. The cover ring 174 may surround the focus ring 172. The inner ring 176 may surround the sidewall 150s1 of the upper portion 151 of the chuck 150 and the top surface 150a2 and the sidewall 150s2 of the lower portion 152 of the chuck 150 as shown in FIG. 2A and FIG. 5. The outer ring 178 may surround the inner ring 176. Materials of the focus ring 172, the cover ring 174, the inner ring 176, and the outer ring 178 may be quartz. In some embodiments, the ring structure 170 is an integrated molding structure, that is, the focus ring 172, the cover ring 174, the inner ring 176 and the outer ring 178 are integrally formed.

FIGS. 2A to 2B illustrate a side view and a cross-sectional view of a chuck structure. Referring to FIGS. 2A to 2B, the chuck structure 145 includes the chuck 150 and the carrier plate 160 below the chuck 150. The chuck 150 includes an upper portion 151 and a lower portion 152, for example. The lower portion 152 may have a lateral dimension greater than the upper portion 151, that is, the lower portion 152 may extend beyond a periphery P1 of the upper portion 151 of the chuck 150. Thus, the top surface 150a2 of the upper portion 151 is, for example, exposed. In some embodiments, the top surface 150a2 is formed between and connected to a sidewall 150s1 of the upper portion 151 and a sidewall 150s1 of the lower portion 152, and the sidewall 150s1, the top surface 150a2 and the sidewall 150s1 form a staircase shape. The lower portion 152 has a thickness larger than the upper portion 151, for example. However, the disclosure is not limited thereto. In alternative embodiments, the lower portion 152 has a thickness smaller than or substantially equal to the upper portion 151.

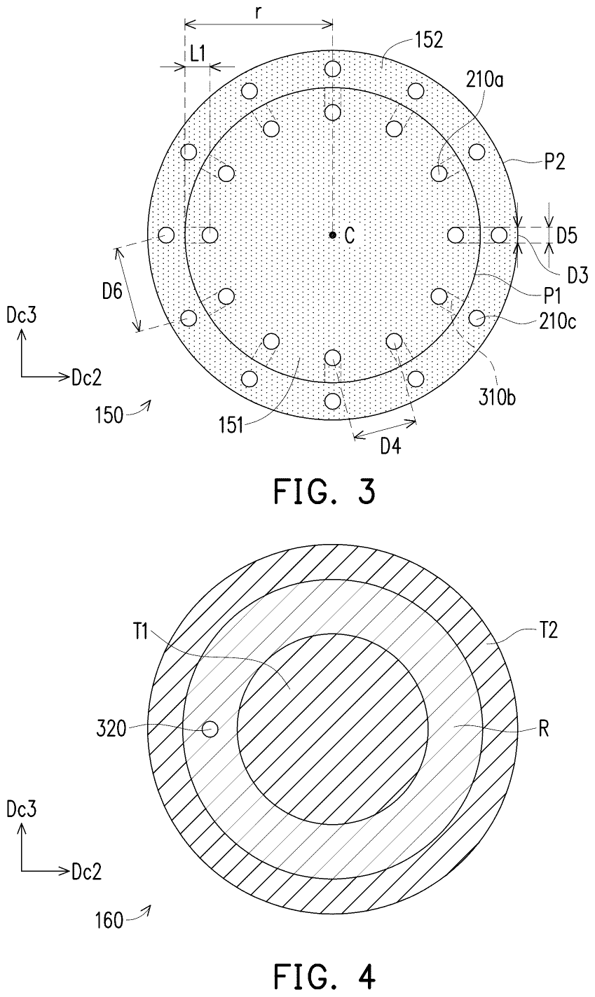

The chuck 150 may further include a plurality of apertures 210 and a gas supply channel 310 therein. The apertures 210 are exposed outside and may be outlets of the gas supply channel 310. The apertures 210 includes first apertures 210a at a first level, second apertures 210b at a second level lower than the first level and third apertures 210c at a third level lower than the second level, for example. The first apertures 210a (as shown in FIG. 2B and FIG. 3) are disposed at the top surface 150a1 of the upper portion 151, for example. The second apertures 210b (as shown in FIG. 2A) are disposed at the sidewall 150s1 of the upper portion 151 of the chuck 150, for example. The third apertures 210c (as shown in FIG. 2B and FIG. 3) are disposed on at the top surface 150a2 of the lower portion 152 of the chuck 150, for example. The sidewall 150s1 is disposed between and connects the top surface 150a1 of the upper portion 151 and the top surface 150a2 of the lower portion 152, for example.

The gas supply channel 310 may extend through the chuck 150 and connect to/communicate with the first apertures 210a, the second apertures 210b and the third apertures 210c, and thus gas flows in the gas supply channel 310 and leaves the gas supply channel 310 through the apertures 210. In some embodiments, the semiconductor processing device 100 further includes a gas controller (e.g. a gas pressure controller) (not shown) connected to the gas supply channel 310, to supply the gas from the gas controller to the apertures 210 through the gas supply channel 310.

The gas supply channel 310 includes first channels 310a, second channels 310b, third channels 310c and fourth channels 310d, for example. The first channels 310a, the second channels 310b, the third channels 310c and the fourth channels 310d may be arranged to form a path between opposite surfaces (e.g., the bottom surface 150b and the top surface 150a1) of the chuck 150. The first channel 310a may connect to/communicate with the first apertures 210a. For example, the first channel 310a extends from a bottom surface 150b of the lower portion 152 of the chuck 150 to a top surface 150a1 of the upper portion 151 of the chuck 150 along a first direction Dc1, to connect the first apertures 210a and the recess R of the carrier plate 160. The first direction Dc1 is a Z direction, for example. In such embodiments, the first channel 310a penetrates through the lower portion 152 and the upper portion 151 vertically. A length along the first direction Dc1 of the first channel 310a may be substantially equal to a total thickness along the first direction Dc1 of the chuck 150.

The second channel 310b may connect to/communicate with the second apertures 210b with the first apertures 210a. In some embodiments, the second channel 310b extends from the first channel 310a to the sidewall 150s1 of the upper portion 151 of the chuck 150 along a second direction Dc2 substantially perpendicular to the first direction Dc1, to connect the second apertures 210b with the first apertures 210a. The second direction Dc2 is a X direction, for example. A length of the second channel 310b may be substantially equal to a distance between the second apertures 210b and the first apertures 210a along the second direction Dc2. In some embodiments, a third direction Dc3 (as shown in FIG. 3) is substantially perpendicular to the first direction Dc1 and the second direction Dc2. The third direction Dc3 is a Y direction, for example.

The third channel 310c and the fourth channel 310d may connect to/communicate with the third apertures 210c with the first apertures 210a and/or the second apertures 210b. For example, the third channel 310c extends from the top surface 150a2 of the lower portion 152 of the chuck 150 along the first direction Dc1, to connect to the third apertures 210c and the fourth channel 310d. The fourth channel 310d extends between the third channel 310c and the first channel 310a along the second direction Dc2, to connect the third channel 310c and the first channel 310a. In some embodiments, the first to third apertures 210a-210c are connected to each other through the first to fourth channel 310a-310d. In some embodiments, the gas supply channel 310 includes a plurality of first channels 310a, and the first channels 310a are arranged along the periphery P1 of the upper portion 151 of the chuck 150. Similarly, the gas supply channel 310 includes a plurality of third channels 310c, and the third channels 310c are arranged along a periphery P2 of the lower portion 152 of the chuck 150. For example, the third channels 310c are arranged to surround the center axis C of the chuck 150. The second channel 310b and the fourth channel 310d extend from the periphery (e.g., P1, P2) of the chuck 150 toward the center axis C of the chuck 150, for example. In some embodiments, a ratio of a length L1 of the second channel 310b along the second direction Dc2 to a radius r of the chuck 150 is in a range of about 1:1 to about 1:3. If the ratio is smaller than 1:1, the leakage issue of the external gas may be caused, and if the ratio is larger than 1:3, the durability strength of the chuck 150 may be influenced. The first channel 310a and the third channel 310c are also referred to as vertical channels, and the second channel 310b and the fourth channel 310d are also referred to as horizontal channels, for example. It is noted that there may be any suitable configuration of the channels to connect the apertures. That is, the channels of the chuck may have any suitable configuration and/or the number.

The second apertures 210b are distributed on the sidewall 150s1 of the upper portion 151 of the chuck 150. A diameter D1 of second apertures 310b is, for example, in a range of about 0.8 mm to about 2 mm. A distance D2 between adjacent second apertures 210b is, for example, in a range of about 5 mm to about 117 mm. The number of the second apertures 310b is, for example, in a range of about 8 to about 162. The second apertures 210b may be distributed uniformly at the sidewall 150s1 of the upper portion 151. For example, the second apertures 210b have the same diameter D1 and the distance D2 between the second apertures 210b is constant. The second apertures 210b may be disposed at the same height and aligned with each other. However, the disclosure is not limited thereto. In alternative embodiments, the second apertures 210b are randomly arranged on the sidewall 150s1 of the upper portion 151.

FIG. 3 illustrates a top view of a chuck of a chuck structure. Referring to FIG. 3, the first apertures 210a are distributed on the top surface 150a1 of the upper portion 151 of the chuck 150, and the third apertures 210c are distributed on the top surface 150a2 of the lower portion 152 of the chuck 150. A diameter D3 of the first apertures 310a is, for example, in a range of about 0.8 mm to about 2 mm. A distance D4 between the first apertures 210a is, for example, in a range of about 5 mm to about 117 mm. The number of the first apertures 310a is, for example, in a range of about 8 to about 162. A diameter D5 of the third apertures 310c is, for example, in a range of about 0.8 mm to about 2 mm. A distance D6 between the third apertures 310c is, for example, in a range of about 5 mm to about 117 mm. The number of the third apertures 310c is in a range of about 8 to about 162. The first apertures 210a may be distributed uniformly at the top surface 150a1 of the upper portion 151 of the chuck 150. For example, the first apertures 210a have the same diameter D3 and the distance D4 between the first apertures 210a is constant. The third apertures 210c may be distributed uniformly at the top surface 150a2 of the lower portion 152 of the chuck 150. For example, the third apertures 210c have the same diameter D5 and the distance D6 between the third apertures 210c is constant. In some embodiments, the diameter D5 of the third apertures 210c is substantially the same as the diameter D3 of the first apertures 210a, and the distance D6 between the third apertures 210c is larger than the distance D4 between the first apertures 210a. For example, as shown in FIG. 3, from a top view, the first apertures 210a are aligned with the third apertures 310c respectively. That is, an imaginary line passing through the first aperture 210a and the third aperture 210c may also pass through the center of the chuck 150. In some embodiments, the diameters D3, D1, D5 of the first apertures 310a to third apertures 310c are respectively substantially equal to the diameters of the first channel 310a to the fourth channel 310d. The diameters D3, D1, D5 of the first apertures 310a to third apertures 310c may be substantially equal to one another. However, the disclosure is not limited thereto. In alternative embodiments, the first apertures 210a are randomly arranged on the top surface 150a1 of the upper portion 151 of the chuck 150 and/or the third apertures 210c are randomly arranged on the top surface 150a2 of the lower portion 152 of the chuck 150.

In some embodiments, as shown in FIGS. 2A and 3, the first, second and third apertures 210a, 210b and 210c are respectively arranged along the periphery P1 of the upper portion 151 of the chuck 150. The second apertures 210b surround the first apertures 210a, and the third apertures 210c surround the second apertures 210b, for example. In some embodiments, since the first apertures 210a are exposed to the semiconductor structure W, the diameter D3, the distance D4 and/or the number of the first apertures 210a are designed for heat dissipation.

FIG. 4 illustrates a top view of a carrier plate of a chuck structure. Referring to FIG. 4 and FIG. 2B, the carrier plate 160 includes a recess R communicated with the first channel 310a. For example, the recess R is disposed at a top surface of the carrier plate 160 and has a depth smaller than a total thickness of the carrier plate 160. The recess R may have an annular shape and divide the top portion of the carrier plate 160 into a first top portion T1 and a second top portion T2. In some embodiments, the first top portion T1 has a circular shape and is also referred to as an inner portion while the second top portion T2 has an annular shape and is also referred to as an outer portion. Top surfaces of the first top portion T1 and second top portion T2 are, for example, substantially coplanar. The recess R is disposed between the first top portion T1 and the second top portion T2. A width of the recess R along the second direction Dc2 is, for example, in a range ofabout 78 mm to about 117 mm.

As shown in FIG. 2B, the carrier plate 160 may further include a gas deliver channel 320 connected to the gas controller (not shown). The gas deliver channel 320 is further connected to/communicated with the recess R. For example, the recess R is disposed between the first channel 310a and the gas deliver channel 320. Thus, a gas (e.g., gas 510 in FIG. 5) supplied by the gas controller flows into the gas supply channel 310 (e.g., the first channel 310a) through the gas deliver channel 320 and the recess R. For example, the gas fills the space within the recess R and then flows into the first channel 310a. The gas may include He, Ar, the like or a combination thereof. In some embodiments, the gas is a diluent and/or a plasma stabilizer during the plasma etching process. However, the disclosure is not limited thereto. The gas may be used to increase the total pressure while keeping the partial pressures of the other gases constant, or species in the gas may improve energy transfer from the “hot” electrons to reactive gas molecules. In some embodiments, the gas is supplied continuously during the semiconductor process and a period between the semiconductor processes.

FIG. 5 illustrates a partial enlarged view of a semiconductor processing device of FIG. 1. Referring to FIG. 5, a gap 520 is formed between the chuck 150 and the ring structure 170 due to the assembly of the chuck 150 and the ring structure 170. If the plasma 530 in the process chamber may enter (e.g., leak) into the gap 520 during the semiconductor process, and the by-product generated from the plasma 530 may be deposited on the sidewall of the gap 520. The by-product may include a polymer particle generated by the process gas such as CₓF_{y} (e.g., C₄F₈ and C₄F₆), and the by-product may be falling onto a surface of the semiconductor structure W to cause defect and/or scrap. For example, the by-product is an etchant by-product and includes C, O, F and Si. For example, the by-product is deposited on the sidewall of the wafer, on the sidewall 150s1 of the upper portion 151 and/or the top surface 150a2 of the lower portion 152 of the chuck 150, and the deposition is also referred to as a by-product deposition. The by-product deposition may cause wafer scrap. In some embodiments, the gap 520 includes a first gap 520a, a second gap 520b connected to the first gap 520a, a third gap 520c connected to the second gap 520b, and a fourth gap 520d connected to third gap 520c. The first gap 520a may extend along the first direction Dc1 between the focus ring 172 and the sidewall of the semiconductor structure W and between the focus ring 172 and the sidewall 150s1 of the upper portion 151 of the chuck 150. The second gap 520b may be disposed between the focus ring 172 and a bottom surface of the semiconductor structure W, and extend along the second direction Dc2 between the focus ring 172 and a bottom surface of the semiconductor structure W and between the focus ring 172 and the sidewall 150s1 of the upper portion 151 of the chuck 150. The third gap 520c may extend along the first direction Dc1 between the focus ring 172 and the sidewall 150s1 of the upper portion 151 of the chuck 150 and between the inner ring 176 and the sidewall 150s1 of the upper portion 151 of the chuck 150. The fourth gap 520d may extend along the second direction Dc2 between the inner ring 176 and the top surface 150a2 of the lower portion 152 of the chuck 150. A width of the gap 520 is, for example, in a range of about 1 mm to about 2 mm. However, the disclosure is not limited thereto. The gap 150 may be formed at any location according to the assembly of the chuck 150 and the ring structure 170.

In some embodiments, the gas 510 supplied by the gas controller may continuously flow into the first channel 310a to the fourth channel 310d and flows out through the first apertures 210a, the second apertures 210b and the third apertures 210c. As shown in FIG. 5, the apertures 210 (e.g., the second aperture 210b and the third aperture 210c) are exposed to and faces the gap 520 between the chuck 510 and the ring structure 170, and thus the gas supply channel 310 is communicated with/connected to the gap 520. Accordingly, the gas 510 may flow into the gap 520 from the gas supply channel 310, and a gas wall 525 may be formed in the gap 520. For example, the gas 520 flows along a path from the fourth gap 520d to the first gap 520a, to form the gas wall 525 in the fourth gap 520d to the first gap 520a. Accordingly, the gas wall 525 may prevent the plasma 530 entering into the gap 520, which may prevent the by-product deposition on the sidewall 150s1 of the upper portion 151 and the top surface 150a2 of the lower portion 152 of the chuck 150. Thus, the wafer scrap and the edge defect of the wafer due to the by-product deposition of the chuck 150 may be also reduced, and the yield may be improved. In addition, since the chuck is prevented from being damaged, the replacement for the chuck may be prevented and the cost may be lowered.

In some embodiments, the ring structure 170 (e.g. the inner ring 176) is tightly attached to the sidewall 150s2 of the lower portion 152 of the chuck 150, and thus the plasma may not enter into the gap therebetween. However, the disclosure is not limited thereto. In alternative embodiments in which the plasma may enter the gap between the ring structure 170 and the sidewall 150s2 of the lower portion 152 of the chuck 150, the gas wall 525 may be further formed in the gap to prevent the entering of the plasma. In other words, if needed, the gas supply channel 310 and the apertures 210 may be configured for the gas wall 525 at any suitable locations, so as to prevent the entering of the plasma.

FIG. 6 illustrates a cross-sectional view of a chuck structure. The chuck structure 145 of FIG. 6 is similar to the chuck structure 145 described above, and the difference lies in the configuration of the gas supply channel 310.

Referring to FIG. 6, the gas supply channel 310 includes a first channel 310a, a plurality of second channels 310b, a plurality of a third channels 310c, a plurality of fourth channels 310d and a plurality of fifth channels 310e. The first channel 310a, the second channels 310b, the third channels 310c, the fourth channels 310d and the fifth channels 310e may be arranged to form a path between opposite surfaces (e.g., the bottom surface 150b and the top surface 150a1) of the chuck 150. In some embodiments, the first channel 310a, the third channels 310c and the fifth channels 310e extend along the first direction Dc1, and the second channels 310b and the fourth channels 310d extend along the second direction Dc2. For example, the first channel 310a, the third channels 310c and the fifth channels 310e are vertical channels, and the second channels 310b and the fourth channels 310d are horizontal channels. The first to fifth channels 310a to 310e are connected, and thus the gas may be provided to the apertures 210 of the chuck 150 through the first to fifth channels 310a to 310e.

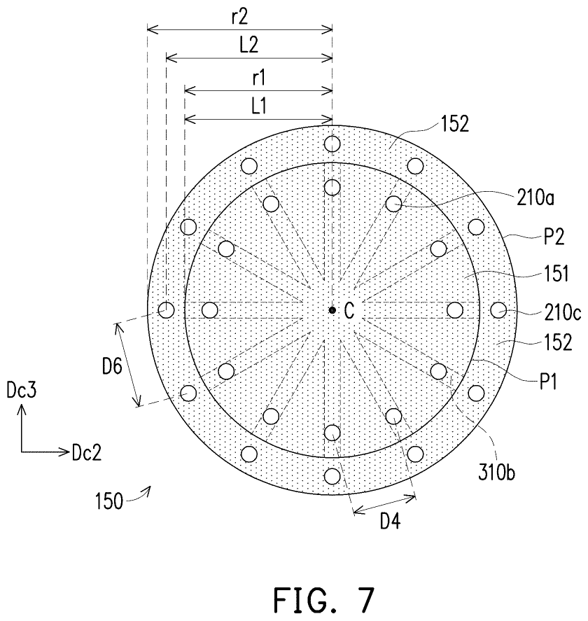

In some embodiments, the gas supply channel 310 includes only one first channel 310a, and the first channel 310a extends along the center axis C of the chuck 150. For example, the first channel 310a penetrates the center portion of the chuck 150 to connect to/communicate with the recess R1 of the carrier plate 160. As shown in FIG. 6, the first channel 310a is connected to a plurality of second channels 310b and a plurality of fourth channels 310d. As shown in FIG. 6 and FIG. 7, the second channels 310b may each extend along a radius of the upper portion 151 of the chuck 150 to connect to the first channel 310a and the second aperture 210b. For example, the second channel 310b continuously extends from the center axis C to a periphery P1 of the upper portion 151, and thus the second channel 310b has a length L1 substantially equal to the radius r1 of the upper portion 151 of the chuck 150. The fourth channels 310d may each extend along a radius of the lower portion 152 of the chuck 150 to connect to the first channel 310a and the third channel 310c. For example, the fourth channels 310d continuously extends from the center axis C to a location inside a periphery P2 of the lower portion 152, and thus the fourth channels 310d has a length L2 smaller to the radius r2 of the lower portion 152 of the chuck 150. The third channel 310d may connect the fourth channel 310d and the third aperture 210c. The fifth channel 310e may connect the second channel 310b and the first aperture 210a. In some embodiments, as shown in FIG. 6, the first channel 310a is also referred to a main channel of the gas supply channel 310, and the second to fifth channels 310b-310e are also referred to branch channels of the gas supply channel 310.

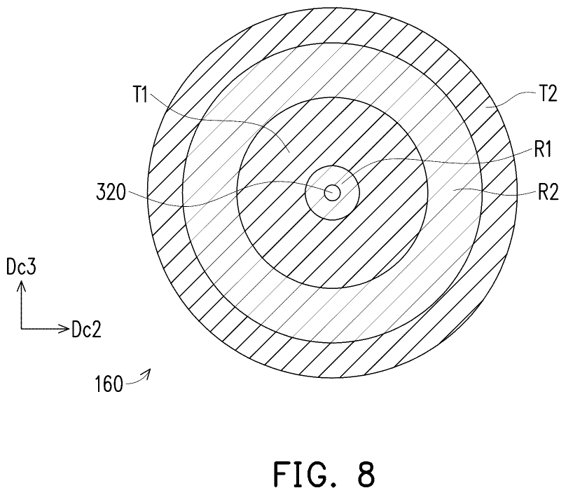

In some embodiments in which the first channel 310a extends along the center axis C of the chuck 150, the recess R1 of the carrier plate 160 is directly disposed below the center axis C. As shown in FIG. 8, the recess R1 is disposed at a top surface of the carrier plate 160 and may be circular-shaped from a top view. A width of the recess R1 along the second direction Dc2 is, for example, in a range of about 0.8 mm to about 2 mm. In some embodiments, the carrier plate 160 further includes a recess R2 at the top surface of the carrier plate 160 and surrounding the recess R1, and the recess R2 is annular-shaped. The recess R1 and the recess R2 may divide the top portion of the carrier plate 160 into a first top portion T1 between the recess R1 and the recess R2 and a second top portion T2 surrounding the recess R1, the first top portion T1 and the recess R2. The first top portion T1 and second top portion T2 have an annular shape, and top surfaces of the first top portion T1 and second top portion T2 are substantially coplanar, for example. However, the disclosure is not limited thereto. The carrier plate 160 may have any suitable configuration.

In some embodiments, similar to that of FIG. 5, the apertures 210 (e.g., the second aperture 210b and the third aperture 210c) are exposed to the gap 520, and thus the gas supply channel 310 is communicated with/connected to the gap 520. Accordingly, the gas 510 may flow into the gap 520 from the gas supply channel 310, and a gas wall 525 may be formed in the gap 520. The gas wall 525 flows along a path from the fourth gap 520d to the first gap 520a. Accordingly, the gas wall 525 may prevent the plasma 530 entering into the gap 520, and thus prevent the by-product deposition on the sidewall 150s1 of the upper portion 151 and the top surface 150a2 of the lower portion 152 of the chuck 150. Accordingly, the wafer scrap and the edge defect of the wafer due to the by-product deposition of the chuck 150 may be reduced. In addition, since the chuck is prevented from being damaged, the replacement for the chuck may be prevented and the cost may be lowered.

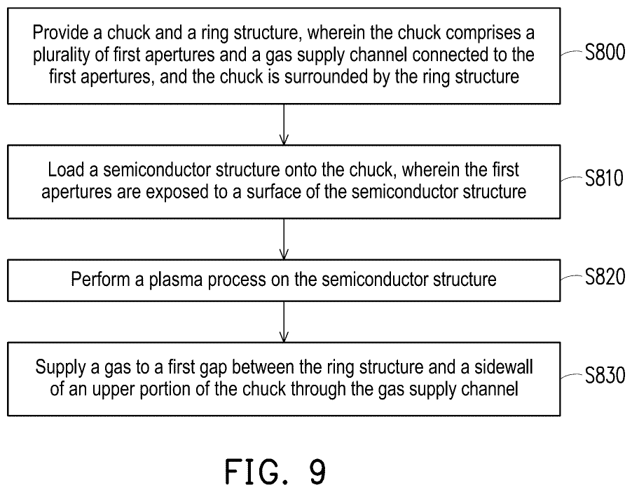

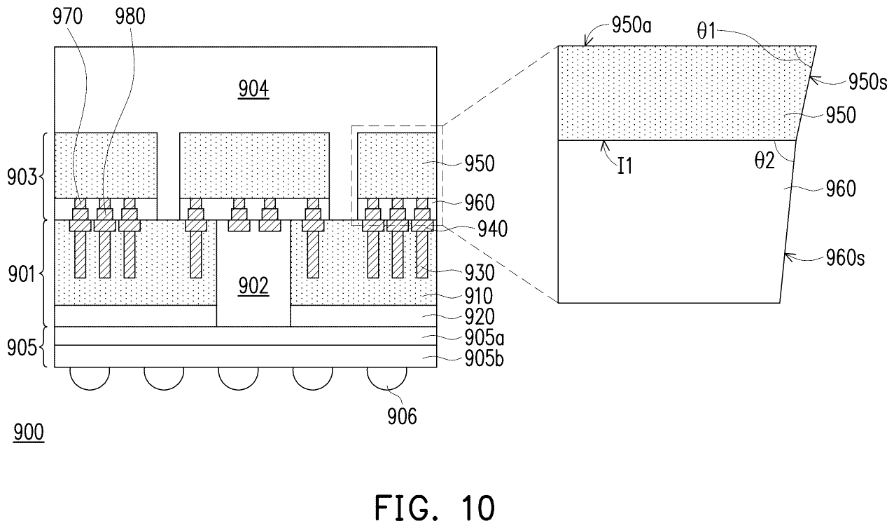

FIG. 9 illustrates a flowchart of a method with use of a semiconductor processing device including a chuck. FIG. 10 illustrates a semiconductor device formed by using the method of FIG. 9.

Referring to FIG. 9, at step S800, a chuck and a ring structure are provided, wherein the chuck includes a plurality of first apertures and a gas supply channel connected to the first apertures, and the chuck is surrounded by the ring structure. FIG. 1 to FIG. 8 illustrate views corresponding to some embodiments of act S800. For example, as shown in FIG. 1, FIG. 2A and FIG. 5, a chuck 150 and a ring structure 170 are provided, wherein the chuck 150 includes a plurality of first apertures 210a and a gas supply channel 310 connected to the first apertures 210a, and the chuck 150 is surrounded by the ring structure 170.

At step S810, a semiconductor structure is loaded onto the chuck, wherein the first apertures are exposed to a surface of the semiconductor structure. FIG. 1 to FIG. 8 illustrate views corresponding to some embodiments of act S810. For example, as shown in FIG. 1, FIG. 2A and FIG. 5, a semiconductor structure W is loaded onto the chuck 150, wherein the first apertures 210a are exposed to a surface (e.g., bottom surface) of the semiconductor structure W.

At step S820, a plasma process is performed on a semiconductor device. FIG. 5 illustrates a view corresponding to some embodiments of act S820. For example, as shown in FIG. 5, a plasma process is performed on the semiconductor structure W by providing a plasma 530 onto the semiconductor structure W in the semiconductor processing device 100. In some embodiments, the plasma process is a plasma etching process such as a dicing process, a deposition process, a diffusion process (e.g., ion implantation process) or the like performed on a semiconductor device. In other words, the plasma process may be any other suitable plasma-based process.

At step S830, a gas is supplied to a first gap between the ring structure and a sidewall of an upper portion of the chuck through the gas supply channel. FIG. 5 illustrates a view corresponding to some embodiments of act S830. For example, as shown in FIG. 5, the gas 510 is supplied to the top surface 150a1 of the upper portion 151 of the chuck 150 and the gap (for example, the third gap 520c) between the ring structure 170 and the sidewall 150s1 of the upper portion 151 of the chuck 150 through the gas supply channel 310. The gas 510 is supplied to the first gap 520a to fourth gap 520d between the ring structure 170 and the chuck 150 and between the ring structure 170 and the semiconductor structure W through the gas supply channel 310, for example.

The gas 510 is supplied in a flow rate of about 3 to about 8 standard cubic centimeter per minute (sccm), for example. Therefore, the gas wall 525 may be formed to prevent the wafer scrap. When the flow rate of the gas is less than 3 sccm, the plasma may enter the gap between the chuck 150 and the ring structure 170 and between the semiconductor structure 150 and the ring structure 170. That is, the plasma may not be blow out by the gas, thus the wafer scrap cannot be prevented. When the flow rate of the gas is greater than 8 sccm, the excessive gas may influence the concentration of the plasma, thus the quality of the processing the semiconductor structure W is influenced.

In some embodiments, after performing the plasma process, a semiconductor device as shown in FIG. 10 is formed. The semiconductor device may be a package structure 900. The package structure 900 may include bottom dies 901, a first encapsulation layer 902 encapsulating the bottom dies 901, top dies 903 disposed on a first side of the bottom dies 901 and the first encapsulation layer 902, a second encapsulation layer 904 encapsulating the top dies 903, a redistribution structure 905 disposed a second side (opposite to the first side) of the bottom dies 901 and the first encapsulation layer 902, and external connectors 906 connected to the redistribution structure 905.

The bottom dies 901 may each include a semiconductor layer 910 and a dielectric layer 920 disposed below the semiconductor layer 910. The semiconductor layer 910 includes conductive features 930 and bonding pads 940 electrically connected to the conductive features 940, for example. The first encapsulation layer 902 encapsulates and surrounds sidewalls of the bottom dies 901, for example. The top dies 903 are each disposed on the first side of the bottom die 901 and the first encapsulation layer 902, for example. The top die 903 is bonded to and electrically connected to the bottom die 901. The top dies 903 may each include a semiconductor layer 950 and a dielectric layer 960 disposed below the semiconductor layer 950. The dielectric layer 960 includes conductive features 970 and bonding pads 980 electrically connected to the conductive features 970, for example. The bonding pads 980 of the top die 903 are bonded to the bonding pads 940 of the bottom die 901. The second encapsulation layer 904 encapsulates and surrounds sidewalls and top surfaces of the top dies 903, for example.

The semiconductor layer 950 of the top die 903 has a surface 950a opposite to an interface I1 between the semiconductor layer 950 and the dielectric layer 960. An included angle θ1 between the surface 950a and a sidewall 950s of the semiconductor layer 950 is in a range of about 85 degrees to about 90 degrees, for example. The surface 950a of the semiconductor layer 950 is at a level of a top surface of the semiconductor layer 950, for example. In some embodiments, the surface 950a of the semiconductor layer 950 is at a level lower than a level of the top surface of the semiconductor layer 950. A thickness of the semiconductor layer 950 of the top die 903 is in a range of about 6 μm to about 9 μm, for example.

The interface I1 is formed between the semiconductor layer 950 and the dielectric layer 960. An included angle θ2 between the interface I1 and a sidewall 960s of the dielectric layer 960 is in a range of about 75 degrees to about 85 degrees, for example. A thickness of the semiconductor layer 950 of the die is in a range of about 10 μm to about 14 μm, for example.

The redistribution structure 905 is disposed the second side (opposite to the first side) of the bottom die 901 and the first encapsulation layer 902, for example. The redistribution structure 905 includes one or more redistribution layers 905a, 905b. The redistribution layers 905a, 905b may each include a dielectric layer (not shown) and conductive features (not shown) formed in the dielectric layers. In some embodiments, the dielectric layer is formed of a polymer, such as polybenzoxazole (PBO), polyimide, benzocyclobutene (BCB), or the like. The dielectric layer may be formed by any acceptable deposition process, such as spin coating, chemical vapor deposition (CVD), laminating, the like, or a combination thereof. The conductive features of the redistribution layer include conductive lines and vias formed of a suitable conductive material such as copper, titanium, tungsten, aluminum, or the like, for example.

The external connectors 906 (may also be referred to as conductive bumps) are formed over the redistribution structure 905 and electrically coupled to the conductive features of the redistribution structure 905, for example. The external connectors 906 may be solder balls, such as Ball Grid Array (BGA) balls, Controlled Collapse Chip Connector (C4) bumps, micro-bumps, and the like.

In alternative embodiments, the plasma process may be any suitable semiconductor processing procedure, and the formed semiconductor device may have any suitable structure.

In some embodiments of the present disclosure, a device includes a chuck. The chuck has an upper portion and a lower portion larger than the upper portion. The chuck includes first apertures, second apertures, third apertures and a gas supply channel. The first apertures are disposed at a top surface of the upper portion of the chuck. The second apertures are disposed at a sidewall of the upper portion of the chuck. The third apertures are disposed at a top surface of the lower portion of the chuck. The gas supply channel extends through the chuck and connecting the first apertures, the second apertures and the third apertures.

In some embodiments, the gas supply channel includes a first channel to a fourth channel. The first channel extends from a bottom surface of the lower portion of the chuck to the upper portion of the chuck, and connects to the first apertures. The second channel extends from the first channel to the sidewall of the upper portion of the chuck, and connects the second apertures with the first apertures. The third channel extends from the lower portion of the chuck to the top surface of the lower portion of the chuck, and connects to the third apertures. The fourth channel extends from the first channel to the third channel, and connects the third apertures with the first apertures and the second apertures.

In some embodiments, the first channel and the third channel extend along a first direction, and the second channel and the fourth channel extend along a second direction substantially perpendicular to the first direction.

In some embodiments, the first channel continuously extends from the bottom surface of the lower portion of the chuck to the top surface of the upper portion of the chuck

In some embodiments, the gas supply channel further includes a fifth channel extending from the second channel to the top surface of the upper portion of the chuck, and the first channel is connected to the first apertures through the second channel and the fifth channel.

In some embodiments, the first channel extends along a center axis of the chuck.

In some embodiments, the second channel extends from the first channel to a periphery of the upper portion of the chuck, and the fourth channel extends from the first channel to a periphery of the lower portion of the chuck.

In some embodiments, the second apertures are distributed uniformly at the sidewall of the upper portion of the chuck, and the third apertures are distributed uniformly at the top surface of the lower portion of the chuck.

In some embodiments, the first apertures, the second apertures and the third apertures are arranged along a periphery of the chuck, respectively.

In some embodiments of the present disclosure, a device includes a chuck, a ring structure, a plurality of first apertures, a plurality of second apertures, and a gas supply channel. The chuck is configured to hold a semiconductor structure. The ring structure surrounds the chuck, wherein a gap is formed between the chuck and the ring structure. The plurality of first apertures is disposed at a first surface of the chuck facing the semiconductor structure. The plurality of second apertures is disposed at a first sidewall of the chuck facing the gap between the chuck and ring structure. The gas supply channel is disposed in the chuck, wherein the gas supply channel connects the first apertures and the second apertures and communicates with the gap.

In some embodiments, the chuck further includes third apertures disposed at a second surface of the chuck facing the gap, and the first sidewall is disposed between the first surface and the second surface.

In some embodiments, the gap is formed between the first sidewall of an upper portion of the chuck and the ring structure, and between the second surface of the lower portion of the chuck and the ring structure.

In some embodiments, the gas supply channel includes a first channel to a fourth channel. The first channel connects to the first apertures. The second channel connects the second apertures with the first apertures. The third channel connects to the third apertures. The fourth channel connects the third apertures with the first channel, wherein the gap is communicated with the second channel and the third channel.

In some embodiments, the gas supply channel further includes a fifth channel, and the first channel is connected to the first apertures through the second channel and the fifth channel.

In some embodiments, the chuck includes an upper portion and a lower portion, and the second channel extends along a radius of the upper portion of the chuck.

In some embodiments, the device further includes a carrier plate disposed below the chuck and having a recess, wherein the gas supply channel is communicated with the recess.

In some embodiments of the present disclosure, a method includes the following steps. A chuck and a ring structure are provided, wherein the chuck includes a plurality of first apertures and a gas supply channel connected to the first apertures, and the chuck is surrounded by the ring structure. A semiconductor structure is loaded onto the chuck, wherein the first apertures are exposed to a surface of the semiconductor structure. A plasma process is performed on the semiconductor structure. A gas is supplied to a first gap between the ring structure and a sidewall of an upper portion of the chuck through the gas supply channel.

In some embodiments, supplying the gas further includes supplying the gas to a second gap between the ring structure and a top surface of a lower portion of the chuck through the gas supply channel.

In some embodiments, supplying the gas further includes supplying the gas to a third gap between the ring structure and a sidewall of the semiconductor structure through the gas supply channel.

In some embodiments, supplying the gas further includes supplying the gas to the semiconductor structure through the gas supply channel and the first apertures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a chuck, having an upper portion and a lower portion larger than the upper portion and comprising:
first apertures, disposed at a top surface of the upper portion of the chuck;
second apertures, disposed at a sidewall of the upper portion of the chuck;
third apertures, disposed at a top surface of the lower portion of the chuck; and
a gas supply channel, extending through the chuck and connecting the first apertures, the second apertures and the third apertures.

2. The device of claim 1, wherein the gas supply channel comprises:
a first channel, extending from a bottom surface of the lower portion of the chuck to the upper portion of the chuck, and connecting to the first apertures;
a second channel, extending from the first channel to the sidewall of the upper portion of the chuck, and connecting the second apertures with the first apertures;
a third channel, extending from the lower portion of the chuck to the top surface of the lower portion of the chuck, and connecting to the third apertures;
a fourth channel, extending from the first channel to the third channel, and connecting the third apertures with the first apertures and the second apertures.

3. The device of claim 2, wherein the first channel and the third channel extend along a first direction, and the second channel and the fourth channel extend along a second direction substantially perpendicular to the first direction.

4. The device of claim 2, wherein the first channel continuously extends from the bottom surface of the lower portion of the chuck to the top surface of the upper portion of the chuck.

5. The device of claim 2, wherein the gas supply channel further comprises a fifth channel extending from the second channel to the top surface of the upper portion of the chuck, and the first channel is connected to the first apertures through the second channel and the fifth channel.

6. The device of claim 5, wherein the first channel extends along a center axis of the chuck.

7. The device of claim 2, wherein the second channel extends from the first channel to a periphery of the upper portion of the chuck, and the fourth channel extends from the first channel to a periphery of the lower portion of the chuck.

8. The device of claim 1, wherein the second apertures are distributed uniformly at the sidewall of the upper portion of the chuck, and the third apertures are distributed uniformly at the top surface of the lower portion of the chuck.

9. The device of claim 1, wherein the first apertures, the second apertures and the third apertures are arranged along a periphery of the chuck, respectively.

10. A device, comprising:
a chuck, configured to hold a semiconductor structure;
a ring structure, surrounding the chuck, wherein a gap is formed between the chuck and the ring structure;
a plurality of first apertures, disposed at a first surface of the chuck facing the semiconductor structure;
a plurality of second apertures, disposed at a first sidewall of the chuck facing the gap between the chuck and ring structure; and
a gas supply channel, disposed in the chuck, wherein the gas supply channel connects the first apertures and the second apertures and communicates with the gap.

11. The device of claim 10, wherein the chuck further comprises third apertures disposed at a second surface of the chuck facing the gap, and the first sidewall is disposed between the first surface and the second surface.

12. The device of claim 11, wherein the gap is formed between the first sidewall of an upper portion of the chuck and the ring structure and between the second surface of the lower portion of the chuck and the ring structure.

13. The device of claim 10, wherein the gas supply channel comprises:
a first channel, connecting to the first apertures;
a second channel, connecting the second apertures with the first apertures;
a third channel, connecting to the third apertures; and
a fourth channel, connecting the third apertures with the first channel, wherein the gap is communicated with the second channel and the third channel.

14. The device of claim 13, wherein the gas supply channel further comprises a fifth channel, and the first channel is connected to the first apertures through the second channel and the fifth channel.

15. The device of claim 13, wherein the chuck comprises an upper portion and a lower portion, and the second channel extends along a radius of the upper portion of the chuck.

16. The device of claim 10, further comprising a carrier plate disposed below the chuck and having a recess, wherein the gas supply channel is communicated with the recess.

17. A method, comprising:
providing a chuck and a ring structure, wherein the chuck comprises a plurality of first apertures and a gas supply channel connected to the first apertures, and the chuck is surrounded by the ring structure;
loading a semiconductor structure onto the chuck, wherein the first apertures are exposed to a surface of the semiconductor structure;
performing a plasma process on the semiconductor structure; and
supplying a gas to a first gap between the ring structure and a sidewall of an upper portion of the chuck through the gas supply channel.

18. The method of claim 17, wherein supplying the gas further comprises supplying the gas to a second gap between the ring structure and a top surface of a lower portion of the chuck through the gas supply channel.

19. The method of claim 17, wherein supplying the gas further comprises supplying the gas to a third gap between the ring structure and a sidewall of the semiconductor structure through the gas supply channel.

20. The method of claim 17, wherein supplying the gas further comprises supplying the gas to the semiconductor structure through the gas supply channel and the first apertures.
